(19) United States
(12) Patent Application Publication
(10) Pub. No.: US 2025/0112087 A1
(43) Pub. Date: Apr. 3, 2025

(54) INTEGRATED CIRCUIT DEVICE AND METHOD FOR FABRICATING THE SAME

(71) Applicant: TAIWAN SEMICONDUCTOR MANUFACTURING COMPANY, LTD., Hsinchu (TW)

(72) Inventors: Hwei-Jay CHU, Hsinchu City (TW); Hsi-Wen TIEN, Hsinchu County (TW); Wei-Hao LIAO, Taichung City (TW); Yu-Teng DAI, New Taipei City (TW); Hsin-Chieh YAO, Hsinchu City (TW); Tzu-Hui WEI, Zhubei City (TW); Chih Wei LU, Hsinchu City (TW); Chan-Yu LIAO, Yunlin County (TW); Li-Ling SU, Taichung County (TW); Chia-Wei SU, Taoyuan City (TW); Yung-Hsu WU, Taipei City (TW); Hsin-Ping CHEN, Hsinchu County (TW)

(73) Assignee: TAIWAN SEMICONDUCTOR MANUFACTURING COMPANY, LTD., Hsinchu (TW)

(21) Appl. No.: 18/480,225

(22) Filed: Oct. 3, 2023

(51) Int. Cl. H01L 21/768; H01L 23/522; H01L 23/528

(52) U.S. Cl. CPC H01L 21/76802; H01L 21/76831; H01L 21/76877; H01L 23/5226; H01L 23/528

(57) ABSTRACT

A method for fabricating an integrated circuit device is provided. The method includes depositing a first dielectric layer; depositing a second dielectric layer over the first dielectric layer; etching a trench opening in the second dielectric layer, wherein the trench opening exposes a first sidewall of the second dielectric layer and a second sidewall of the second dielectric layer, the first sidewall of the second dielectric layer extends substantially along a first direction, and the second sidewall of the second dielectric layer extends substantially along a second direction different from the first direction in a top view; forming a via etch stop layer on the first sidewall of the second dielectric layer, wherein the second sidewall of the second dielectric layer is free from coverage by the via etch stop layer; forming a conductive line in the trench opening; and forming a conductive via over the conductive line.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15C illustrate a method for fabricating an integrated circuit device at various intermediate stages of manufacture according to some embodiments of the present disclosure.

FIG. 16 is a schematic cross-sectional view of an integrated circuit device according to some embodiments of the present disclosure.

FIG. 17 is a schematic cross-sectional view of an integrated circuit device according to some embodiments of the present disclosure.

FIGS. 18A-24C illustrate a method for fabricating an integrated circuit device at various intermediate stages of manufacture according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.”

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 130rees or at other orientations) and the spatially relative descriptors used herein may likewise be interpreted accordingly.

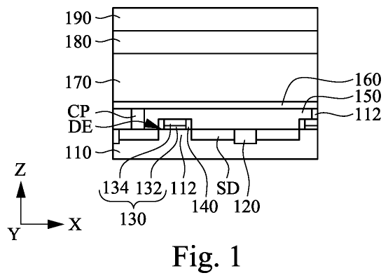

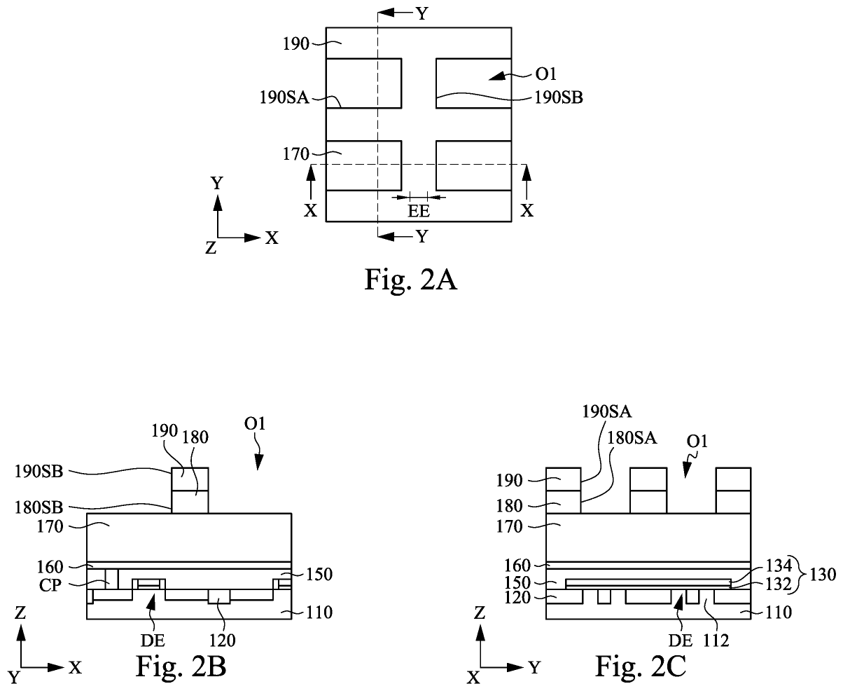

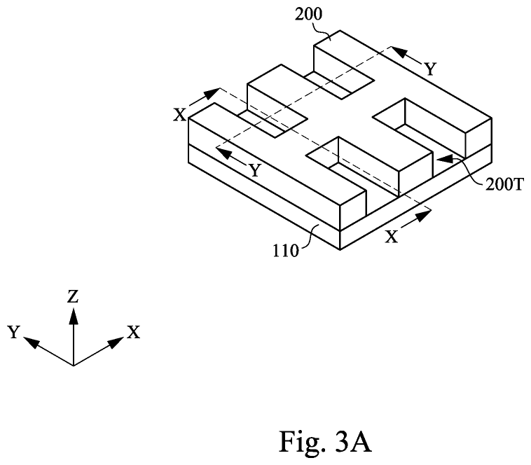

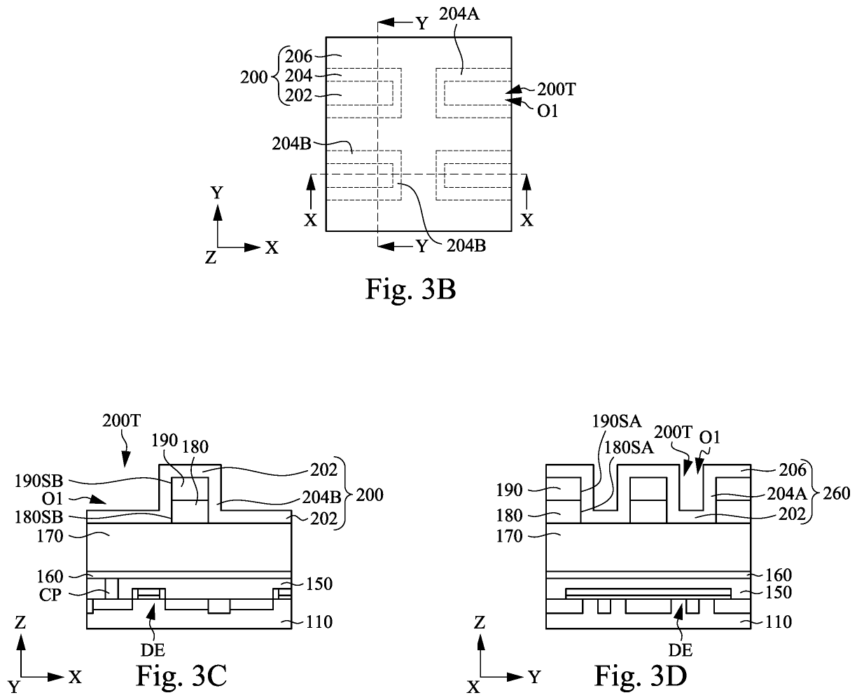

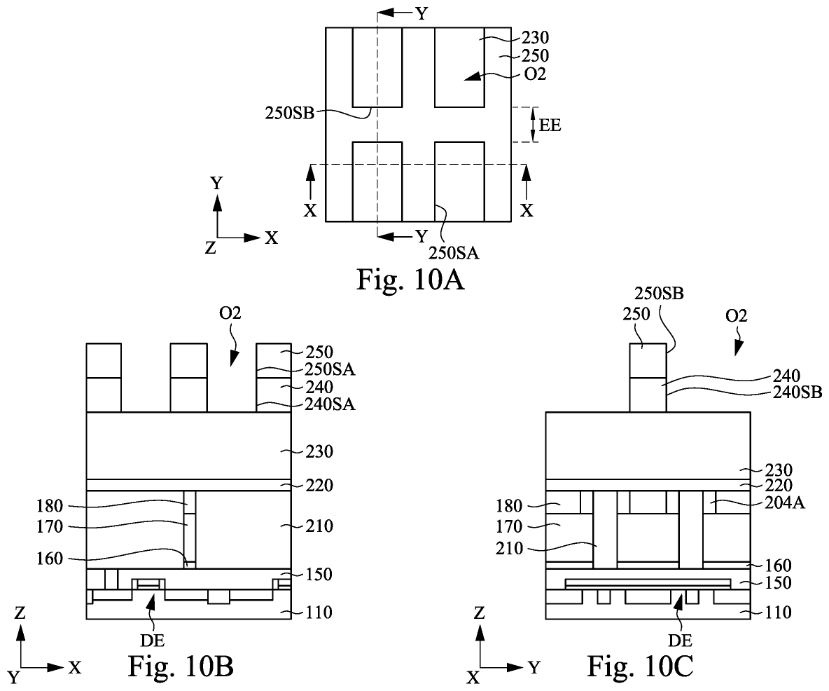

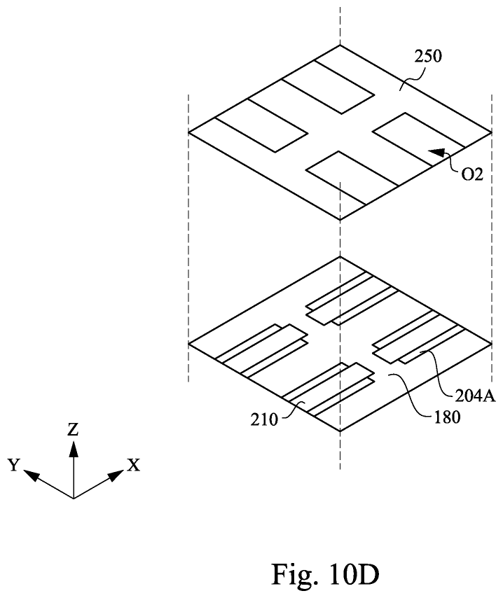

FIGS. 1-15C illustrate a method for fabricating an integrated circuit device at various intermediate stages of manufacture according to some embodiments of the present disclosure. FIGS. 2A, 3B, 4B, 5A, 6A, 7A, 8A, 10A, 11A, 12A, 13A, 14A, and 15A are top views of the integrated circuit device at the intermediate stages of fabrication process according to some embodiments of the present disclosure. FIGS. 2B, 3C, 4C, 5B, 6B, 7B, 8B, 9A, 10B, 11B, 12B, 13B, 14B, and 15B illustrate cross-sectional views taken along a line X-X in FIGS. 2A, 3B, 4B, 5A, 6A, 7A, 8A, 10A, 11A, 12A, 13A, 14A, and 15A, respectively. FIGS. 2C, 3D, 4D, 5C, 6C, 7C, 8C, 9B, 10C, 11C, 12C, 13C, 14C, and 15C illustrate cross-sectional views taken along a line Y-Y in FIGS. 2A, 3B, 4B, 5A, 6A, 7A, 8A, 10A, 11A, 12A, 13A, 14A, and 15A, respectively. FIG. 1 is a cross-sectional view taken along the line X-X. FIGS. 3A and 3B are perspective schematic views of the integrated circuit device at the intermediate stages of fabrication process according to some embodiments of the present disclosure. FIG. 10D is a schematic view of the integrated circuit device showing mappings of a first layer and a second layer over the first layer. It is understood that additional operations may be provided before, during, and after the operations shown by FIGS. 1-15C, and some of the operations described below can be replaced or eliminated for additional embodiments of the method. The order of the operations/processes may be interchangeable.

Reference is made to FIG. 1. In some embodiments, a substrate 110 is provided. The substrate 110 may comprise a substantially monocrystalline material, for example, bulk silicon. In some other embodiments, the substrate 110 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 110 may comprise an active layer of a semiconductor-on-insulator (SOI) substrate. An SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Other substrates, such as multi-layered or gradient substrates, may also be used.

In some embodiments, one or more active and/or passive devices DE are formed on chip regions of the substrate 110. In the depicted embodiments, the devices DE are fin field-effect transistors (FinFET) that are three-dimensional metal oxide semiconductor field effect transistor (MOSFET) structure formed in fin-like strips of semiconductor protrusions referred to as fins 112. The cross-section shown in FIG. 1 is taken along a longitudinal axis of the fin 112 in a direction parallel to the direction of the current flow between the source/drain regions SD. The fin 112 may be formed by patterning the substrate 110 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 112 by etching a trench into the substrate 110 using, for example, reactive ion etching (RIE). FIG. 1 illustrates a single fin 112, although the substrate 110 may comprise any number of fins. In some other embodiments, the devices DE can be planar transistors or gate-all-around (GAA) transistors. The GAA transistor may be fabricated by channel stacking techniques, and stacked nanosheet (NS) can enhance the on-current (Ion) at fixed footprint.

STI regions 120 are formed on opposing sidewalls of the fin 112 as illustrated in FIG. 1. STI regions 120 may be formed by depositing one or more dielectric materials (e.g., silicon oxide) to completely fill the trenches around the fins and then recessing the top surface of the dielectric materials. The dielectric materials of the STI regions 120 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 120 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 120 such that an upper portion of fins 112 protrudes from surrounding insulating STI regions 120. In some cases, the patterned hard mask used to form the fins 112 may also be removed by the planarization process.

In some embodiments, a gate structure 130 of the FinFET device DE illustrated in FIG. 1 is a high-k, metal gate (HKMG) gate structure that may be formed using a gate-last process flow. In a gate-last process flow, a sacrificial dummy gate structure (not shown) is formed after forming the STI regions 120. The dummy gate structure may comprise a dummy gate dielectric, a dummy gate electrode, and a hard mask. First a dummy gate dielectric material (e.g., silicon oxide, silicon nitride, or the like) may be deposited. Next, a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 120. As described in greater detail below, the dummy gate structure may be replaced by the HKMG gate structure 130 as illustrated in FIG. 1. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 1, source/drain regions SD and spacers 140 of the transistor device DE are formed, for example, self-aligned to the dummy gate structures. Spacers 140 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 140 along the sidewalls of the dummy gate structures extending laterally onto a portion of the surface of the fin 112.

Source/drain regions SD are semiconductor regions in direct contact with the semiconductor fin 112. In some embodiments, the source/drain regions SD may comprise heavily-doped regions and relatively lightly-doped drain extensions, or LDD regions. Generally, the heavily-doped regions are spaced away from the dummy gate structures using the spacers 140, whereas the LDD regions may be formed prior to forming spacers 140 and, hence, extend under the spacers 140 and, in some embodiments, extend further into a portion of the semiconductor fin 112 below the dummy gate structure. The LDD regions may be formed, for example, by implanting dopants (e.g., As, P, B, In, or the like) using an ion implantation process.

The source/drain regions SD may comprise an epitaxially grown region. For example, after forming the LDD regions, the spacers 140 may be formed and, subsequently, the heavily-doped source and drain regions may be formed self-aligned to the spacers 140 by first etching the fins to form recesses, and then depositing a crystalline semiconductor material in the recess by a selective epitaxial growth (SEG) process that may fill the recess and may extend further beyond the original surface of the fin 112 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of dopants may be introduced into the heavily-doped source and drain regions SD either in situ during SEG, or by an ion implantation process performed after the SEG, or by a combination thereof.

Once the source/drain regions SD are formed, a first interlayer dielectric (ILD) layer (e.g., lower portion of the ILD layer 150) is deposited over the source/drain regions SD. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer. The HKMG gate structures 130, illustrated in FIG. 1, may then be formed by first removing the dummy gate structures using one or more etching techniques, thereby creating recesses between respective spacers 140. Next, a replacement gate dielectric layer 132 comprising one more dielectrics, followed by a replacement gate metal layer 134 comprising one or more metals, are deposited to completely fill the recesses. Excess portions of the gate dielectric layer 132 and the gate metal layer 134 may be removed from over the top surface of first ILD using, for example, a CMP process. The resulting structure, as illustrated in FIG. 1, may include remaining portions of the gate dielectric layer 132 and the gate metal layer 134 inlaid between respective spacers 140.

The gate dielectric layer 132 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer 134 may be a multilayered metal gate stack comprising a barrier layer, a work function layer, and a gate-fill layer formed successively on top of gate dielectric layer 132. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

After forming the HKMG gate structure 130, a second ILD layer (e.g., upper portion of the ILD layer 150) is deposited over the first ILD layer, and these ILD layers are in combination referred to as the ILD layer 150, as illustrated in FIG. 1. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, PVD, ALD, PEALD, PECVD, SACVD, FCVD, spin-on, and/or the like, or a combination thereof.

The contact plugs 112 may be formed in the ILD layer 150 using photolithography, etching and deposition techniques. For example, a patterned mask may be formed over the ILD layer 150 and used to etch openings that extend through the ILD layer 150 to expose the gate structure 130 as well as the source/drain regions SD. Thereafter, conductive liner may be formed in the openings in the ILD layer 150. Subsequently, the openings are filled with a conductive fill material. The liner comprises barrier metals used to reduce out-diffusion of conductive materials from the contact plugs 112 into the surrounding dielectric materials. In some embodiments, the liner may comprise two barrier metal layers. The first barrier metal comes in contact with the semiconductor material in the source/drain regions SD and may be subsequently chemically reacted with the heavily-doped semiconductor in the source/drain regions SD to form a low resistance ohmic contact, after which the unreacted metal may be removed. For example, if the heavily-doped semiconductor in the source/drain regions SD is silicon or silicon-germanium alloy semiconductor, then the first barrier metal may comprise Ti, Ni, Pt, Co, other suitable metals, or their alloys, and may form silicide with the source/drain regions SD. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD layer 150. The resulting conductive plugs extend into the ILD layer 150 and constitute contact plugs 112 making physical and electrical connections to the gates or source/drain nodes of electronic devices, such as the tri-gate FinFET device DE illustrated in FIG. 1.

An etch stop layer 160 is deposited over the ILD layer 150. The etch stop layer 160 may include a suitable dielectric material different from that of the ILD layer 150. For example, the etch stop layer 160 may include silicon nitride, silicon carbide, other high-k materials, metal oxides, the like, or the combination thereof.

An ILD layer 170 is deposited over the etch stop layer 160, and then a dielectric layer 180 is deposited over the ILD layer 170. For example, the ILD layer 170 and the dielectric layer 180 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The ILD layer 170 may include a dielectric material different from that of the dielectric layer 180. The ILD layer 170 and the dielectric layer 180 may include the same or different dielectric materials. The dielectric materials used to form the ILD layer 170 and the dielectric layer 180 may include SiC, SiO₂, SiOC, SiN, SiCN, SiON, SiOCN, the like, or the combination thereof, and be deposited using any suitable method, such as spin-on coating, CVD, ALD, PVD, the like, or the combination thereof.

A hard mask layer 190 is deposited over the dielectric layer 180. The hard mask layer 190 may include a suitable dielectric material different from that of the dielectric layer 180. For example, the hard mask layer 190 may include TiN, TiO, W, WdC, HfO, ZrO, ZnO, TiZrO, SiC, SiO₂, SiOC, SiN, SiCN, SiON, SiOCN, AlOx, AlON, other high-k materials, metal oxides, the like, or the combination thereof.

Reference is made to FIGS. 2A-2C. A trench patterning process is performed to form trench openings O1 extending through the hard mask layer 190 and the dielectric layer 180. The trench openings O1 may have their lengthwise directions substantially parallel with a direction, such as direction X. Stated differently, the trench openings O1 may extend substantially along the direction X. The trench patterning process may include a photolithography process and an etching process. The photolithography process may include coating a photoresist layer over the hard mask layer 190, exposing the photoresist to a pattern, performing post-exposure bake processes, and developing the resist to form a patterned mask including the photoresist over the hard mask layer 190. In some embodiments, a minimum end-to-end space EE between two trench openings O1 aligned along the direction X is defined by a line width of the patterned mask, which is constrained by a photolithography limitation of the photolithography process. Using the patterned mask including the photoresist as an etch mask, a first etch process is performed to etch trench openings O1 in the hard mask layer 190. The patterned mask including the photoresist may then be removed by suitable stripping process. Using the hard mask layer 190 as etch mask, a second etch process may be performed to extend trench openings O1 through the dielectric layer 180, and exposing the underlying ILD layer 170. The first and second etch processes may stop by end point detection and/or etch time control. The first and second etching processes may include a dry etch process, a wet etch process, or the combination thereof.

After the etching processes, the trench openings O1 may expose sidewalls of the hard mask layer 190 and the dielectric layer 180. For example, the hard mask layer 190 has sidewalls 190SA and sidewalls 190SB exposed by the trench openings O1, in which the sidewalls 190SA and sidewalls 190SB respectively extends along the direction X and a direction Y perpendicular from the direction X. And, the dielectric layer 180 has sidewalls 180SA and sidewalls 180SB exposed by the trench openings O1, in which the sidewalls 180SA and sidewalls 180SB respectively extend along the direction X and a direction Y perpendicular from the direction X. In some embodiments, at this stage, the two adjacent sidewalls 190SB/180SB is spaced apart by the minimum end-to-end space EE.

Reference is made to FIGS. 3A-3D. An etch stop layer 200 is conformally deposited over the structure of FIGS. 2A-2C. The etch stop layer 200 may include a suitable dielectric material different from that of the dielectric layer 180 and the ILD layer 170. For example, the etch stop layer 200 may include can be SiC, SiO₂, SiOC, SiN, SiCN, SiON, SiOCN, AlON, AlO, other high-k materials, other metal oxides, the like, or the combination thereof. The etch stop layer 200 may be deposited by PVD, CVD, ALD, spin-on coating, the like, or the combination thereof.

In some embodiments, since the etch stop layer 200 is deposited in a conformal manner, the deposited etch stop layer 200 have trenches 200T according to the profile of the trench openings O1. For example, the etch stop layer 200 may have bottom portions 202 extending along bottoms of the trench openings O1, side portions 204 extending along sidewalls of the trench openings O1, and top portions extending along a top surface of the hard mask layer 190. The bottom portion 202 may be in contact with a top surface of the ILD layer 170. The side portions 204 may be in contact with the sidewalls of the hard mask layer 190 and the underlying dielectric layer 180 exposed by the trench openings O1. In the present embodiments, the side portions 204 include side portions 204A and side portions 204B, respectively extending along the direction X and the direction Y, in which the side portions 204A may be in contact with the sidewalls 190SA and 180SA of the hard mask layer 190 and the underlying dielectric layer 180, and the side portions 204B may be in contact with the sidewalls 190SB and 180SB of the hard mask layer 190 and the underlying dielectric layer 180.

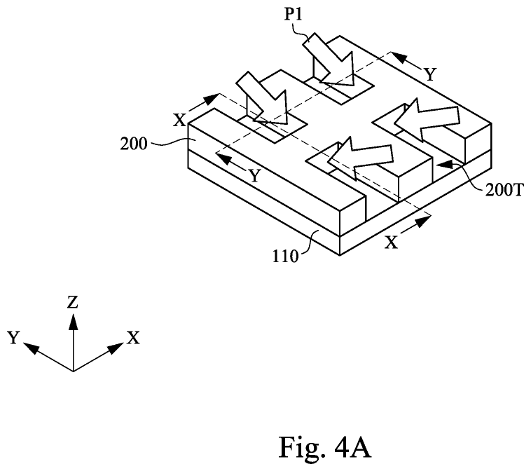

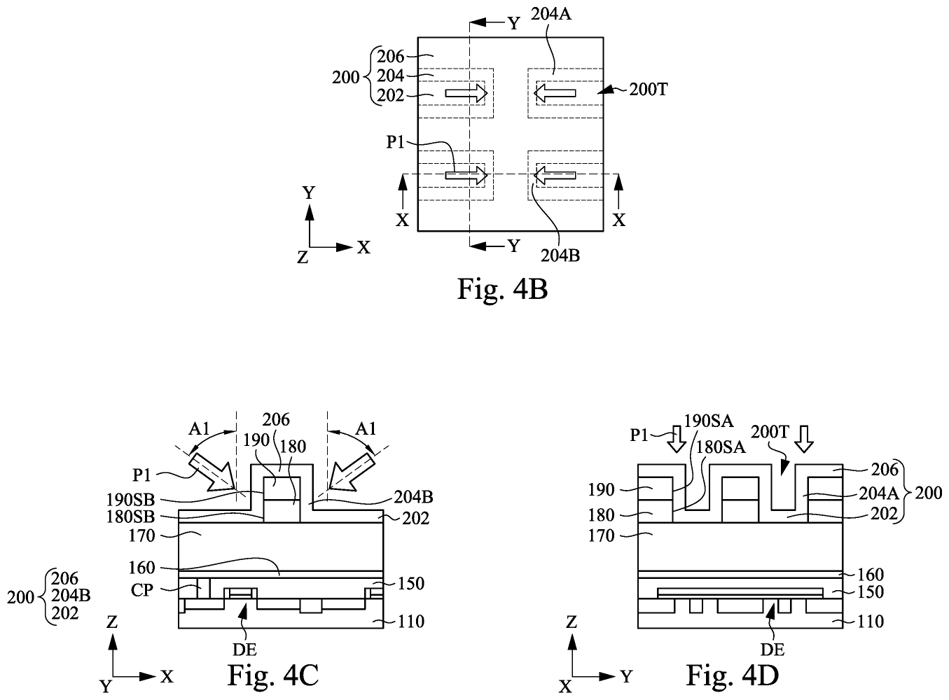

Reference is made to FIGS. 4A-4D. A directional ion beam etch process P1 is performed to remove the side portions 204B of the etch stop layer 200 from the sidewalls 190SB of the hard mask layer 190 and the sidewalls 180SB of the dielectric layer 180, while the side portions 204A of the etch stop layer 200 remains on sidewalls 190SA of the hard mask layer 190 and the sidewalls 180SA of the dielectric layer 180. In some embodiments, the directional ion beam etch process P1 can be performed with parallel (or substantially parallel) ion beams, and/or with ion beams that are not parallel with each other. For example, when the directional ion beam etch process P1 is performed with parallel ion beams, the ion beams of the directional ion beam etch process P1 is performed substantially along a direction tilted with respect a direction normal to the substrate 110 (e.g., direction Z), in which the direction of the ion beams is substantially in a X-Z plane as shown in FIG. 4C and along the direction Z in the Y-Z plane as shown in FIG. 4D. In some alternative embodiments, the directional ion beam etch process P1 may be performed with non-parallel ion beams having an angle distribution with its direction. In various embodiments, the ion beams of the directional ion beam etch process P1 may be substantially parallel and optionally having an angle distribution, and may tilt with the direction Z in the X-Z plane as shown in FIG. 4C. As shown in FIG. 4C, the direction of the directional ion beam etch process P1 is tilted at a first angle A1 with respect to the direction Z in X-Z plane, in which the first angle A1 may be in a range from about 10 degrees to about 70 degrees. The ion beam angle distribution ranges from about 0 degree to about 50 degrees for the ion beam incident with the angle A1 with respect to the direction Z in X-Z plane. In various embodiments, the ion beams of the directional ion beam etch process P1 may be substantially parallel and optionally having an angle distribution with the direction Z in the Y-Z plane as shown in FIG. 4D. In some embodiments, in FIG. 4D, the direction of the directional ion beam etch process P1 is tilted at a second angle with respect to the direction Z in Y-Z plane, in which the second angle may be less than the first angle A1. For example, the second angle is almost equal to zero, or greater than zero and less than about 10 degrees. The ion beam angle distribution ranges from about 0 degree to about 5 degrees for the ion beams in Y-Z plane.

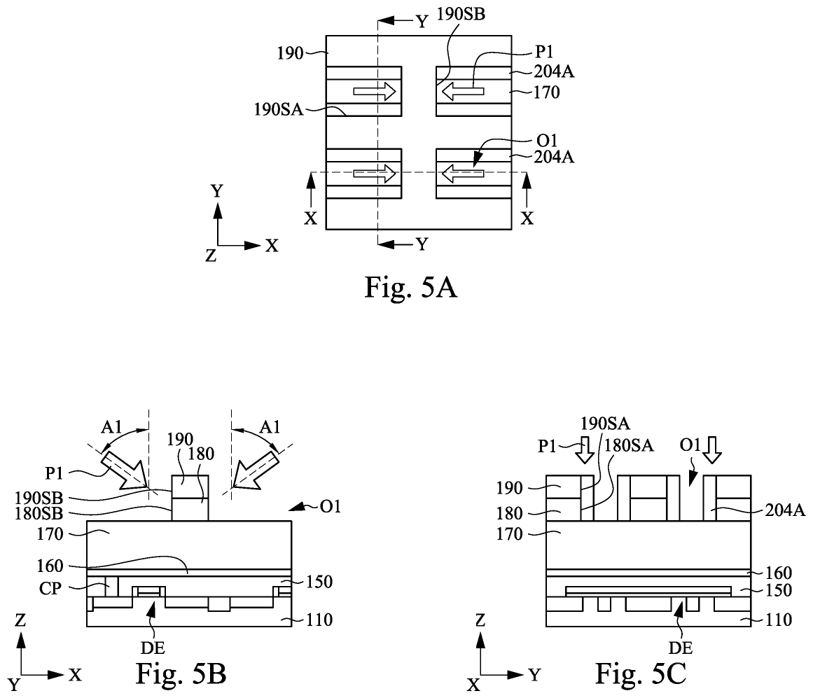

The directional ion beam etch process P1 may also remove the bottom portions 202 of the etch stop layer 200 from the top surface of the ILD layer 170 and remove the top portions 206 of the etch stop layer 200 from the top surface of the hard mask layer 190. The resulted structure is shown in FIGS. 5A-5C. After the directional ion beam etch process P1, the top surface of the ILD layer 170, the sidewalls 190SB of the hard mask layer 190 and the sidewalls 180SB of the dielectric layer 180 are exposed. The side portions 204A covering the sidewalls 190SA of the hard mask layer 190 and the sidewalls 180SA of the dielectric layer 180 may be referred to as via etch stop layers 204A hereinafter. Stated differently, the directional ion beam etch process P1 is performed to form via etch stop layers 204A in the trench openings O1.

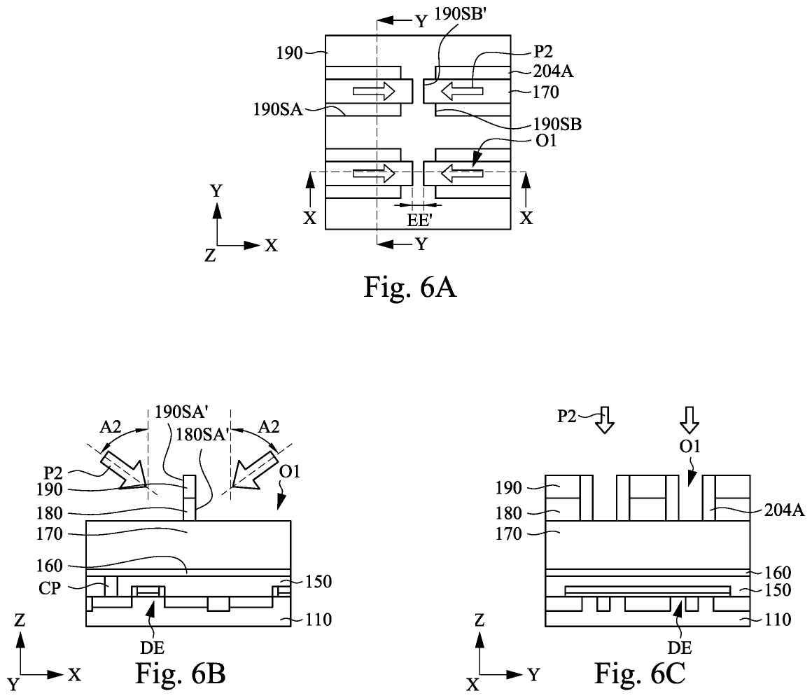

Reference is made to FIGS. 6A-6C. A directional ion beam etch process P2 is performed to push at least portions of the sidewalls 190SB of the hard mask layer 190 and the sidewalls 180SB of the dielectric layer 180 (referring to FIGS. 5A-5C) uncovered by the via etch stop layers 204A. The pushed portions of the of the sidewalls 190SB of the hard mask layer 190 and the sidewalls 180SB of the dielectric layer 180 (referring to FIGS. 5A-5C) may be respectively referred to as sidewalls 190SB′ and sidewalls 180SB′ hereinafter. The resulted structure is shown in FIGS. 6A-6C. In some embodiments of the present disclosure, through the directional ion beam etch process P2, the two adjacent sidewalls 190SB′/180SB′ are spaced apart by the end-to-end space EE′, which is less than the minimum end-to-end space EE constrained by the photolithography limitation of the photolithography process.

A directional ion beam etch process P2 is performed to remove portions of the hard mask layer 190 and the dielectric layer 180 adjacent the trench openings O1 along the direction X, while the via etch stop layers 204A remains in the trench openings O1 and covering the sidewalls 190SA of the hard mask layer 190 and the sidewalls 180SA of the dielectric layer 180. In some embodiments, the directional ion beam etch process P2 can be performed with parallel (or substantially parallel) ion beams, and/or with ion beams that are not parallel with each other. For example, when the directional ion beam etch process P2 is performed with parallel ion beams, the ion beams of the directional ion beam etch process P2 is performed along a direction tilted with respect a direction normal to the substrate 110 (e.g., direction Z), in which the direction of the ion beams is substantially in a X-Z plane as shown in FIG. 6B and along the direction Z in the Y-Z plane as shown in FIG. 6C. In some alternative embodiments, the directional ion beam etch process P2 may be performed with non-parallel ion beams having an angle distribution with its direction. In various embodiments, the ion beams of the directional ion beam etch process P2 may be substantially parallel and optionally having an angle distribution, and may tilt with the direction Z in the X-Z plane as shown in FIG. 4C. As shown in FIG. 6B, the direction of the directional ion beam etch process P2 is tilted at a third angle A3 with respect to the direction Z in the X-Z plane, in which the third angle A3 may be in a range from about 10 degrees to about 70 degrees. The ion beam angle distribution ranges from about 0 to about 50 degrees for the ion beam incident with the angle A3 with respect to the direction Z in X-Z plane. In various embodiments, the ion beams of the directional ion beam etch process P2 may be substantially parallel and optionally having an angle distribution with the direction Z in the Y-Z plane as shown in FIG. 6C. In some embodiments, in FIG. 6C, the direction of the directional ion beam etch process P2 is tilted at a fourth angle with respect to the direction Z in the Y-Z plane, in which the fourth angle may be less than the third angle A1. For example, the fourth angle is almost equal to zero, or greater than zero and less than about 10 degrees. The ion beam angle distribution ranges from about 0 degree to about 5 degrees for the ion beams in Y-Z plane.

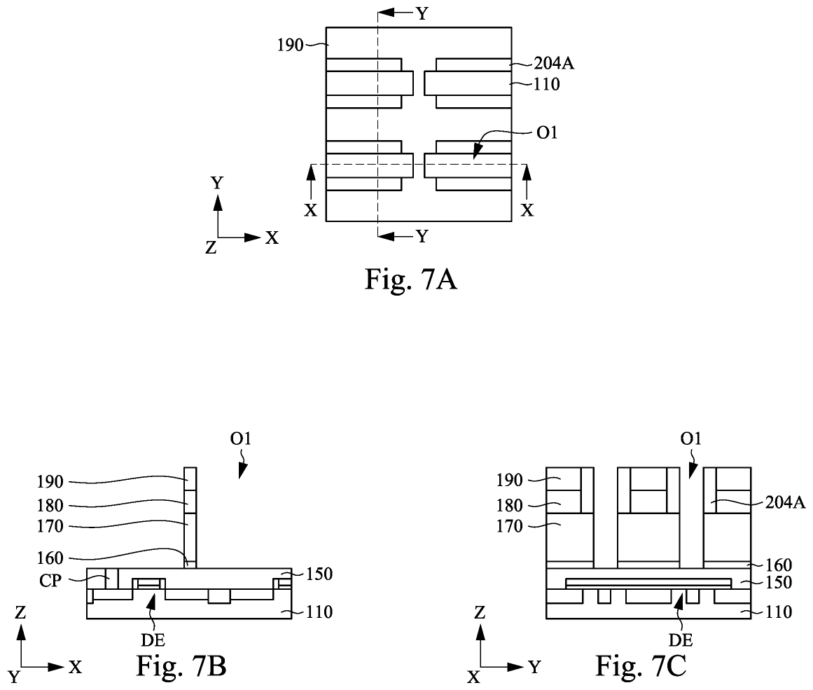

Reference is made to FIGS. 7A-7C. An etching process is performed to extend the trench openings O1 into the ILD layer 170. The hard mask layer 190 and the via etch stop layer 204A may serve as etch masks during the etching process. The etching process may etch the ILD layer 170 at a faster rate than it etches the etch stop layer 160, and therefore the etch stop layer 160 may serve as an etch stop layer during the first etching process. After etching the trench openings O1 in the ILD layer 170, a liner removal process (also referred to as etching/clean process) may be performed to remove an exposed portion of the etch stop layer 160, thereby extending the trench openings O1 into the etch stop layer 160. Through the etching processes and the liner removal process, top ends of the contact plugs 112 may be exposed by the trench openings O1.

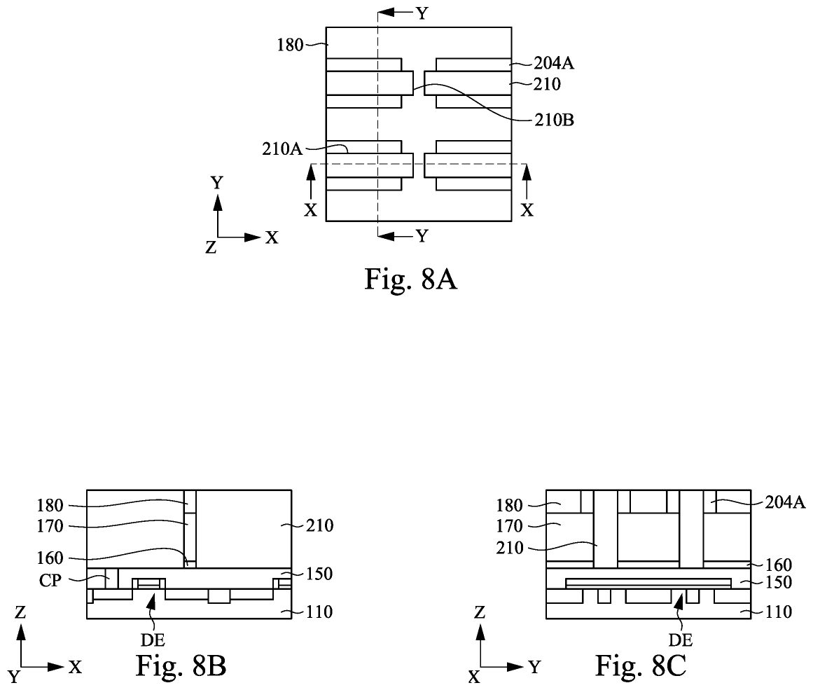

Reference is made to FIGS. 8A-8C. Metal lines 210 are formed in the opening O1. Formation of the metal lines 210 may include filling the trench openings O1 with one or more conductive materials. In some embodiments, the one or more conductive materials may include copper (Cu), tungsten (W), aluminum (Al), titanium (Ti), titanium nitride (TiN), tantalum nitride (TaN), Ta, Co, Ru, Mo, Ir, other metal alloy, other metals, the like, or the combination thereof. In some embodiments, one or more barrier/adhesion layers may be deposited into the trench openings O1 prior to depositing the one or more conductive materials. The one or more barrier/adhesion layers may comprise titanium, titanium nitride, tantalum, tantalum nitride, other metal nitrides, other metal carbide, metal oxide, other metals, the like, or the combination thereof, and may be formed using PVD, CVD, ALD, or the like. A CMP process may be performed to remove excess materials of the conductive materials external to the trench openings O1. The CMP process may also remove the hard mask layer 190 from the via etch stop layers 204A and the dielectric layer 180.

In some embodiments of the present disclosure, top portions of the metal lines 210 are surrounded by the via etch stop layers 204A, and bottom portions of the metal lines 210 are surrounded by the ILD layer 170. For example, lower portions of sidewalls of the metal lines 210 are free from coverage by the via etch stop layers 204A. The bottom ends of the via etch stop layer 204A may be higher than a bottom surface of the metal lines 210.

In some embodiments of the present disclosure, in the top view of FIG. 8A, the metal lines 210 protrude from the via etch stop layers 204A along the direction X. For example, the metal lines 210 has sidewalls 210A extending along the direction X and sidewalls 210B extending along the direction Y, the via etch stop layers 204A are in contact with the sidewalls 210A, and the sidewalls 210B are misaligned with ends of the via etch stop layers 204A.

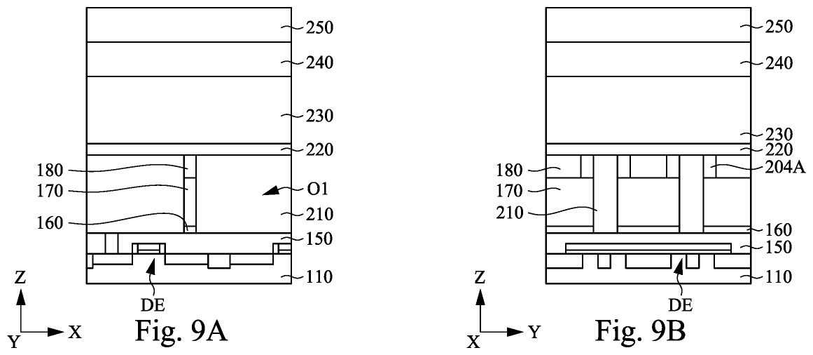

Reference is made to FIGS. 9A and 9B. A dielectric cap layer 220 is deposited over the dielectric layer 180. The dielectric cap layer 220 may include a suitable dielectric material different from that of the dielectric layer 180. For example, the dielectric cap layer 220 may include be SiC, SiO₂, SiOC, SiN, SiCN, SiON, SiOCN, the like, or the combination thereof. The dielectric cap layer 220 can be formed by spin-on coating, CVD, ALD, PVD, the like, or the combination thereof.

An ILD layer 230 is deposited over the dielectric cap layer 220, and then a dielectric layer 240 is deposited over the ILD layer 230. For example, the ILD layer 230 may include be SiC, SiO₂, SiOC, SiN, SiCN, SiON, SiOCN, the like, or the combination thereof. The ILD layer 230 can be formed by spin-on coating, CVD, ALD, PVD, the like, or the combination thereof. For example, the ILD layer 230 and the dielectric layer 240 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The ILD layer 230 may include a dielectric material different from that of the dielectric layer 240. The ILD layer 230 and the dielectric layer 240 may include the same or different dielectric materials. The dielectric materials used to form the ILD layer 230 and the dielectric layer 240 may include SiC, SiO₂, SiOC, SiN, SiCN, SiON, SiOCN, the like, or the combination thereof, and be deposited using any suitable method, such as spin-on coating, CVD, ALD, PVD, the like, or the combination thereof.

A hard mask layer 250 is deposited over the dielectric layer 240. The hard mask layer 250 may include a suitable dielectric material different from that of the dielectric layer 240. For example, the hard mask layer 250 may include TiN, TiO, W, WdC, HfO, ZrO, ZnO, TiZrO, SiC, SiO₂, SiOC, SiN, SiCN, SiON, SiOCN, AlOx, AlON, other high-k materials, metal oxides, the like, or the combination thereof.

Reference is made to FIGS. 10A-10D. A trench patterning process is performed to form trench openings O2 extending through the hard mask layer 250 and the dielectric layer 240. The trench openings O2 may have their lengthwise directions substantially parallel with a direction, such as direction Y. Stated differently, the trench openings O2 may extend substantially along the direction Y. The trench patterning process may include a photolithography process and an etching process. The photolithography process may include coating a photoresist layer over the hard mask layer 250, exposing the photoresist to a pattern, performing post-exposure bake processes, and developing the resist to form a patterned mask including the photoresist over the hard mask layer 250. In some embodiments, a minimum end-to-end space EE between two trench openings O2 aligned along the direction Y is defined by a line width of the patterned mask, which is constrained by a photolithography limitation of the photolithography process. Using the patterned mask including the photoresist as an etch mask, a first etch process is performed to etch trench openings O2 in the hard mask layer 250. The patterned mask including the photoresist may then be removed by suitable stripping process. Using the hard mask layer 250 as etch mask, a second etch process may be performed to extend trench openings O2 through the dielectric layer 240, and exposing the underlying ILD layer 230. The first and second etch processes may stop by end point detection and/or etch time control. The first and second etching processes may include a dry etch process, a wet etch process, or the combination thereof.

After the etching processes, the trench openings O2 may expose sidewalls of the hard mask layer 250 and the dielectric layer 240. For example, the hard mask layer 250 has sidewalls 250SA and sidewalls 250SB exposed by the trench openings O1, in which the sidewalls 250SA and sidewalls 250SB respectively extends along the direction Y and the direction X. And, the dielectric layer 180 has sidewalls 180SA and sidewalls 180SB exposed by the trench openings O2, in which the sidewalls 180SA and sidewalls 180SB respectively extend along the direction Y and the direction X. In some embodiments, at this stage, the two adjacent sidewalls 250SB/240SB is spaced apart by the minimum end-to-end space EE.

Reference is made to FIGS. 11A-11C. An etch stop layer 260 is conformally deposited over the structure of FIGS. 10A-10D. The etch stop layer 260 may include a suitable dielectric material different from that of the dielectric layer 240 and the ILD layer 230. For example, the etch stop layer 260 may include can be SiC, SiO₂, SiOC, SiN, SiCN, SiON, SiOCN, AlON, AlO, other high-k materials, other metal oxides, the like, or the combination thereof. The etch stop layer 260 may be deposited by PVD, CVD, ALD, spin-on coating, the like, or the combination thereof.

In some embodiments, since the etch stop layer 260 is deposited in a conformal manner, the deposited etch stop layer 260 have trenches 260T according to the profile of the trench openings O2. For example, the etch stop layer 260 may have bottom portions 262 extending along bottoms of the trench openings O2, side portions 264 extending along sidewalls of the trench openings O2, and top portions extending along a top surface of the hard mask layer 250. The bottom portion 262 may be in contact with a top surface of the ILD layer 230. The side portions 264 may be in contact with the sidewalls of the hard mask layer 250 and the underlying dielectric layer 240 exposed by the trench openings O2. In the present embodiments, the side portions 264 include side portions 264A and side portions 264B, respectively extending along the direction X and the direction Y, in which the side portions 264A may be in contact with the sidewalls 250SA and 240SA of the hard mask layer 250 and the underlying dielectric layer 240, and the side portions 264B may be in contact with the sidewalls 250SB and 240SB of the hard mask layer 250 and the underlying dielectric layer 240.

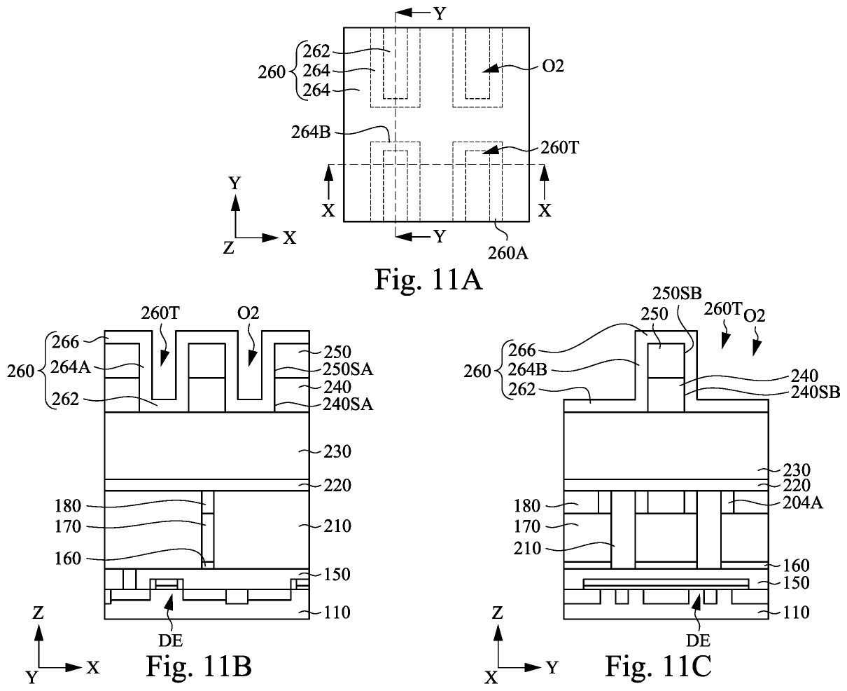

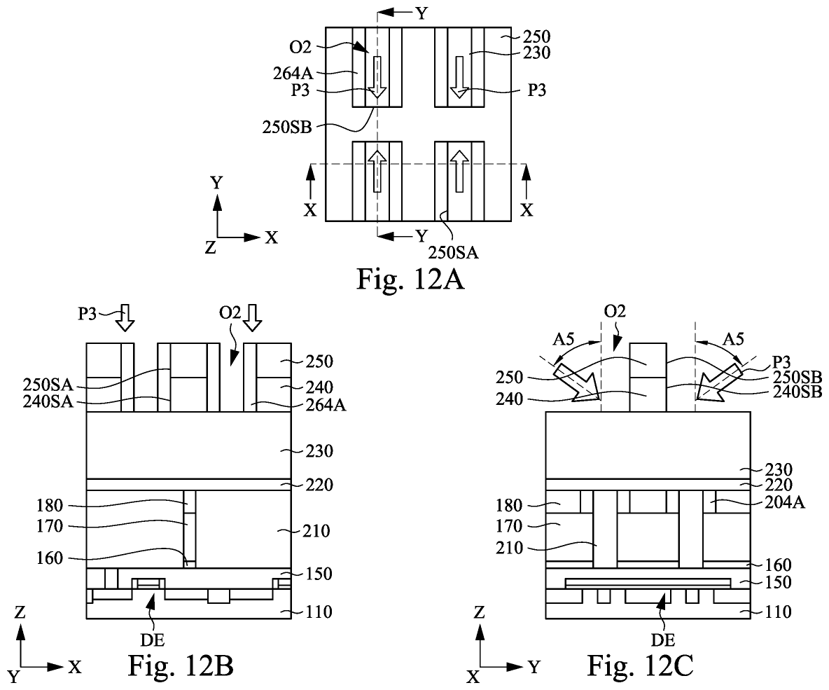

Reference is made to FIGS. 12A-12C. A directional ion beam etch process P3 is performed to remove the side portions 264B of the etch stop layer 260 (referring to FIGS. 11A-11C) from the sidewalls 250SB of the hard mask layer 250 and the sidewalls 240SB of the dielectric layer 240, while the side portions 264A of the etch stop layer 260 remains on sidewalls 250SA of the hard mask layer 250 and the sidewalls 240SA of the dielectric layer 240. In some embodiments, the directional ion beam etch process P3 can be performed with parallel (or substantially parallel) ion beams, and/or with ion beams that are not parallel with each other. For example, when the directional ion beam etch process P3 is performed with parallel ion beams, the ion beams of the directional ion beam etch process P3 is performed substantially along a direction tilted with respect the direction normal to the substrate 110 (e.g., direction Z), in which the direction of the ion beams is along the direction Z in a X-Z plane as shown in FIG. 12B and substantially in the Y-Z plane as shown in FIG. 12C. In some alternative embodiments, the directional ion beam etch process P3 may be performed with non-parallel ion beams having an angle distribution with its direction. In various embodiments, the ion beams of the directional ion beam etch process P3 may be substantially parallel and optionally having an angle distribution, and may tilt with the direction Z in the Y-Z plane as shown in FIG. 12C. As shown in FIG. 12C, the direction of the directional ion beam etch process P3 is tilted at a fifth angle A5 with respect to the direction Z in the Y-Z plane, in which the fifth angle A5 may be in a range from about 10 degrees to about 70 degrees. The ion beam angle distribution ranges from about 0 degree to about 50 degrees for the ion beam incident with the angle A5 with respect to the direction Z in Y-Z plane. In various embodiments, the ion beams of the directional ion beam etch process P3 may be substantially parallel and optionally having an angle distribution with the direction Z in the X-Z plane as shown in FIG. 12B. In some embodiments, in FIG. 12B, the direction of the directional ion beam etch process P3 is tilted at a sixth angle with respect to the direction Z in X-Z plane, in which the sixth angle may be less than the fifth angle A5. For example, the sixth angle is almost equal to zero, or greater than zero and less than about 10 degrees. The ion beam angle distribution ranges from about 0 degree to about 5 degrees for the ion beam in X-Z plane.

The directional ion beam etch process P3 may also remove the bottom portions 262 of the etch stop layer 260 (referring to FIGS. 11A-11C) from the top surface of the ILD layer 230 and remove the top portions 266 of the etch stop layer 260 (referring to FIGS. 11A-11C) from the top surface of the hard mask layer 250. After the directional ion beam etch process P3, the top surface of the ILD layer 230, the sidewalls 250SB of the hard mask layer 250 and the sidewalls 240SB of the dielectric layer 240 are exposed. The side portions 264A covering the sidewalls 250SA of the hard mask layer 250 and the sidewalls 240SA of the dielectric layer 240 may be referred to as via etch stop layers 264A hereinafter. Stated differently, the directional ion beam etch process P3 is performed to form via etch stop layers 264A in the trench openings O2.

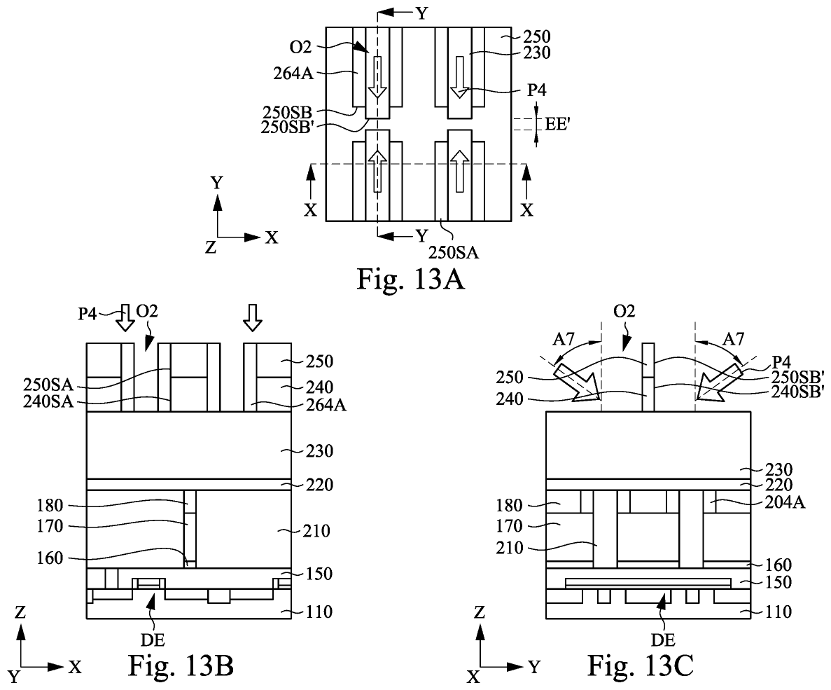

Reference is made to FIGS. 13A-13C. A directional ion beam etch process P4 is performed to push at least portions of the sidewalls 250SB of the hard mask layer 250 and the sidewalls 240SB of the dielectric layer 240 (referring to FIGS. 12A-12C) uncovered by the via etch stop layers 264A. The pushed portions of the sidewalls 250SB of the hard mask layer 250 and the sidewalls 240SB of the dielectric layer 240 (referring to FIGS. 12A-12C) may be respectively referred to as sidewalls 250SB′ and sidewalls 240SB′ hereinafter. The resulted structure is shown in FIGS. 13A-13C. In some embodiments of the present disclosure, through the directional ion beam etch process P4, the two adjacent sidewalls 250SB′/240SB′ are spaced apart by the end-to-end space EE′, which is less than the minimum end-to-end space EE constrained by the photolithography limitation of the photolithography process.

A directional ion beam etch process P4 is performed to remove portions of the hard mask layer 250 and the dielectric layer 240 adjacent the trench openings O2 along the direction Y, while the via etch stop layers 264A remains in the trench openings O2 and covering the sidewalls 250SA of the hard mask layer 250 and the sidewalls 240SA of the dielectric layer 240. In some embodiments, the directional ion beam etch process P4 can be performed with parallel (or substantially parallel) ion beams, and/or with ion beams that are not parallel with each other. For example, when the directional ion beam etch process P4 is performed with parallel ion beams, the ion beams of the directional ion beam etch process P4 is performed along a direction tilted with respect a direction normal to the substrate 110 (e.g., direction Z), in which the direction of the ion beams is along the direction Z in a X-Z plane as shown in FIG. 13B and substantially in the Y-Z plane as shown in FIG. 13C. In some alternative embodiments, the directional ion beam etch process P4 may be performed with non-parallel ion beams having an angle distribution with its direction. In various embodiments, the ion beams of the directional ion beam etch process P4 may be substantially parallel and optionally having an angle distribution and may tilt with the direction Z in a Y-Z plane as shown in FIG. 13C. As shown in FIG. 13C, the direction of the directional ion beam etch process P4 is tilted at a seventh angle A7 with respect to the direction Z in the Y-Z plane, in which the seventh angle A7 may be in a range from about 10 degrees to about 70 degrees. The ion beam angle distribution ranges from about 0 degree to about 50 degrees for the ion beam incident with the angle A7 with respect to the direction Z in Y-Z plane. In various embodiments, the ion beams of the directional ion beam etch process P4 may be substantially parallel and optionally having an angle distribution with the direction Z in the X-Z plane as shown in FIG. 13B. In some embodiments, in FIG. 13B, the direction of the directional ion beam etch process P4 is tilted at an eighth angle with respect to the direction Z in the X-Z plane, in which the eighth angle may be less than the seventh angle A7. For example, the eighth angle is almost equal to zero, or greater than zero and less than about 10 degrees. The ion beam angle distribution ranges from about 0 degree to about 5 degrees for the ion beams in X-Z plane.

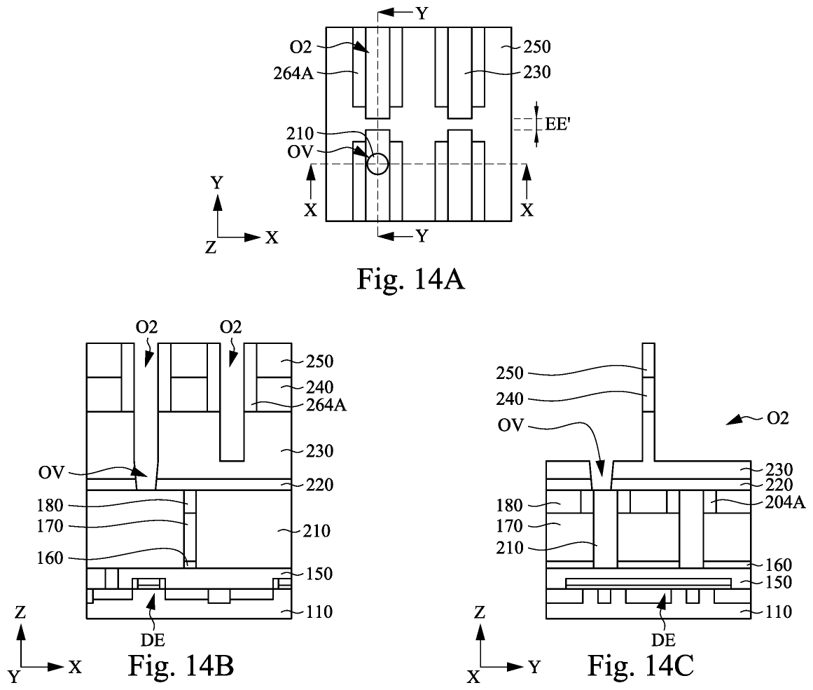

Reference is made to FIGS. 14A-14C. A trench and via etching process is performed. The trench and via etching process may include a trench etching process and a via etching process performed prior to or after the trench etching process. The trench etching process is performed to extend the trench openings O2 into the ILD layer 230. The hard mask layer 250 and the etch stop layer 240 may serve as etch masks during the trench and via etching process. The via etching process is performed to etching a via opening OV in the ILD layer 230. Prior to the via etching process, a photolithography process is performed to form a patterned mask defining the pattern of the via opening OV. The photolithography process may include coating a photoresist layer, exposing the photoresist to a pattern, performing post-exposure bake processes, and developing the resist to form a patterned mask including the photoresist. In some embodiments, the trench/via etching process(es) may etch the ILD layer 230 at a faster rate than it etches the dielectric cap layer 220, and therefore the dielectric cap layer 220 may serve as an etch stop layer during the trench/via etching process. In some alternative embodiments, due to the presence of the via etch stop layer 204A, the trench/via etching process(es) may etch the ILD layer 230 and the dielectric cap layer 220 at a similar rate. After etching the trench openings O2 and the via opening OV in the ILD layer 230, a liner removal process (also referred to as etching/clean process) may be performed to remove an exposed portion of the dielectric cap layer 220, thereby extending the via openings OV into the dielectric cap layer 220. Through the etching processes and the liner removal process, top surfaces of the metal lines 210 and the via etch stop layer 204A may be exposed by the trench openings OV.

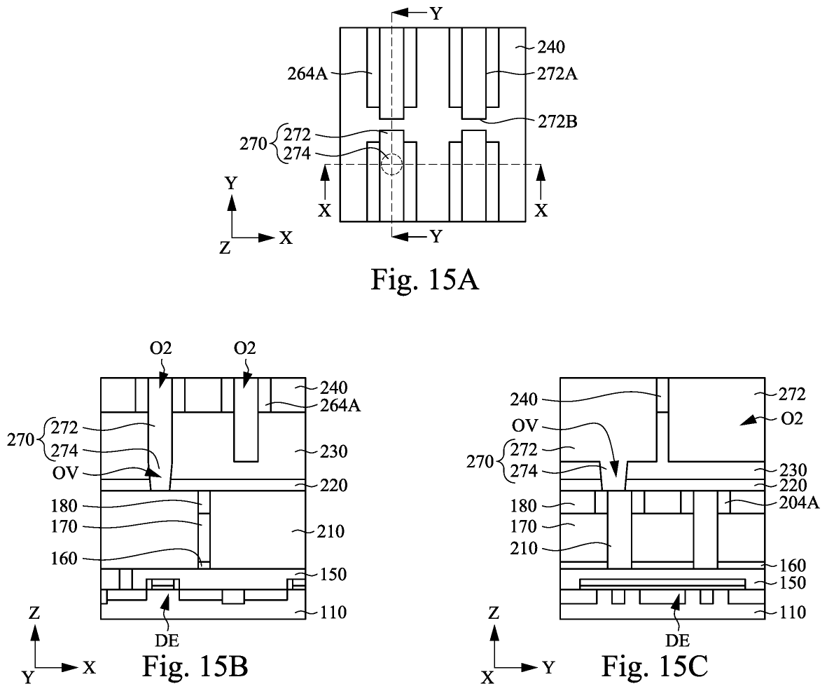

Reference is made to FIGS. 15A-15C. Metal features 270 are formed in the opening O2 and the via opening OV. Formation of the metal features 270 may include filling the trench openings O2 and the via opening OV with one or more conductive materials, followed by a CMP process to remove excess materials of the conductive materials. In some embodiments, the one or more conductive materials may include copper (Cu), tungsten (W), aluminum (Al), titanium (Ti), titanium nitride (TiN), tantalum nitride (TaN), Ta, Co, Ru, Mo, Ir, the like, other metal alloy, other metals, or the combination thereof. In some embodiments, one or more barrier/adhesion layers may be deposited into the trench openings O2 and the via opening OV prior to depositing the one or more conductive materials. The one or more barrier/adhesion layers may comprise titanium, titanium nitride, tantalum, tantalum nitride, other metal nitrides, other metal carbide, metal oxide, other metals, the like, or the combination thereof, and may be formed using PVD, CVD, ALD, or the like. A CMP process may be performed to remove excess materials of the conductive materials external to the trench openings O2. The CMP process may also remove the hard mask layer 250 from the via etch stop layers 264A and the dielectric layer 240.

The metal features 270 may include a metal via 272 in the via opening OV and metal lines 274 in the trench openings O2. The metal via 272 connect the metal lines 210 to the metal lines 274. In the present embodiments, a width of the metal via 272 is less than a width of the metal lines 210. Due to overlay shift, the metal via 272 may be misaligned with the underlying metal lines 210, not exactly match the underlying metal lines 210. For example, the metal via 272 may extend beyond a sidewall of the metal lines 210. Stated differently, a first portion of a bottom surface of the metal via 272 may be in contact with a sidewall of the metal lines 210, and second portion of a bottom surface of the metal via 272 may be free of contacting the metal line 210. In absence of the via etch stop layer 204A, due to overlay shift, the dielectric layer 180 surrounding the underlying metal lines 210 may be exposed and damaged in the formation of the via opening OV, and thus the metal via formed in the opening may have undesired profile, such as in contact with a sidewall of the metal lines 210, which may lead to current leakage concern.

In embodiments of the present disclosure, with the configuration of the via etch stop layers 204A and the dielectric layer 180 surrounding the underlying metal lines 210 may not be exposed and damaged in the formation of the via opening OV. Thus, the metal via 272 formed in the opening may be in contact with top surfaces of the metal lines 210 and the via etch stop layer 204A, and not in contact with a sidewall of the metal lines 210, thereby addressing the leakage concern.

In some embodiments of the present disclosure, top portions of the metal lines 272 are surrounded by the via etch stop layers 264A, and bottom portions of the metal lines 272 are surrounded by the ILD layer 230. For example, lower portions of sidewalls of the metal lines 272 are free from coverage by the via etch stop layers 264A. The bottom ends of the via etch stop layer 264A may be higher than a bottom surface of the metal lines 272.

In some embodiments of the present disclosure, in the top view of FIG. 15A, the metal lines 272 protrude from the via etch stop layers 264A along the direction Y. For example, the metal lines 272 has sidewalls 272A extending along the direction Y and sidewalls 272B extending along the direction X, the via etch stop layers 264A are in contact with the sidewalls 272A, and the sidewalls 272B are misaligned with ends of the via etch stop layers 264A.

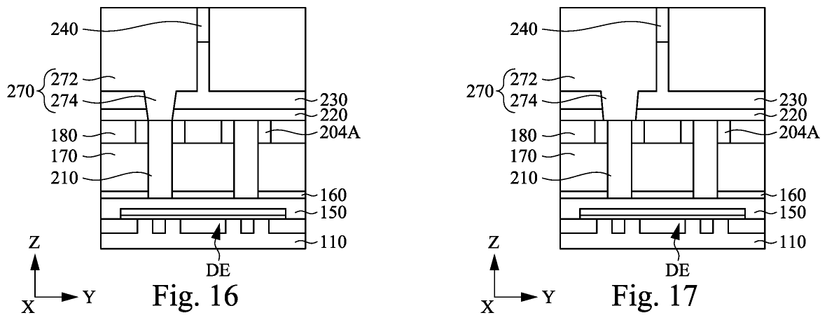

FIG. 16 is a schematic cross-sectional view of an integrated circuit device according to some embodiments of the present disclosure. Details of the present embodiments are similar to those illustrated in the embodiments of FIGS. 1-15C, except that the metal via 272 is aligned with the underlying metal lines 210, and matches the underlying metal lines 210. For example, the metal via 272 may not extend beyond a sidewall of the metal lines 210. Stated differently, an entirety of the bottom surface of the metal via 272 may be in contact with a top surface of the metal lines 210. In the present embodiments, the metal via 272 formed in the opening may be in contact with top surfaces of the metal lines 210, and not in contact with a sidewall of the metal lines 210. Other details of the present embodiments are similar to the embodiments of FIGS. 1-15C, and not repeated herein.

FIG. 17 is a schematic cross-sectional view of an integrated circuit device according to some embodiments of the present disclosure. Details of the present embodiments are similar to those illustrated in the embodiments of FIGS. 1-15C, except that a bottom surface of the metal via 272 may extend beyond opposite sidewalls of the metal lines 210. In the present embodiments, a width of the metal via 272 is greater than a width of the metal lines 210. Stated differently, a bottom critical dimension (BCD) is larger than a width of the metal lines 210, such that an entirety of the bottom surface of the metal via 272 may be in contact with a top surface of the metal lines 210 and top ends of the two via etch stop layers 204A. In the present embodiments, the metal via 272 formed in the opening may be in contact with top surfaces of the metal lines 210, and not in contact with a sidewall of the metal lines 210. Other details of the present embodiments are similar to the embodiments of FIGS. 1-15C, and not repeated herein.

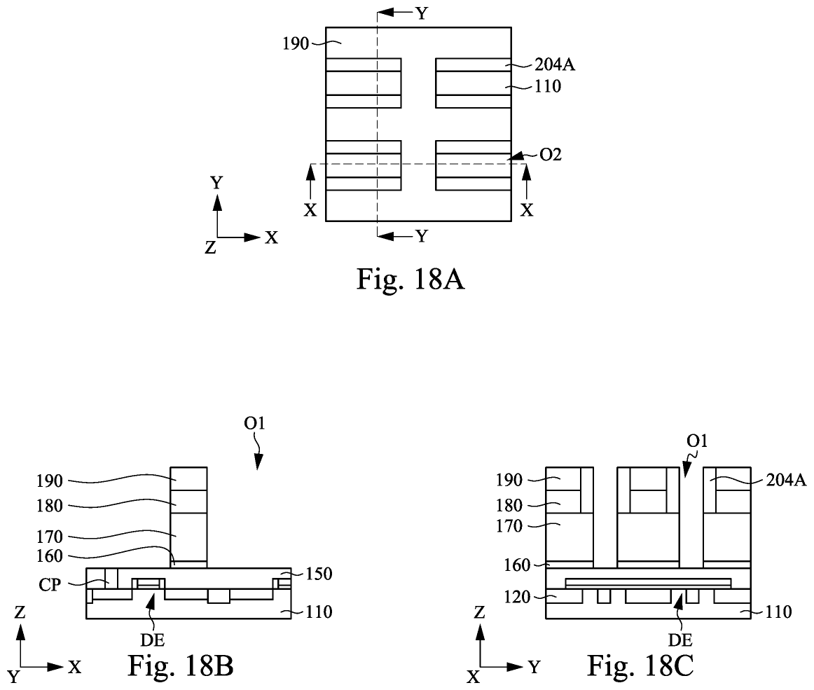

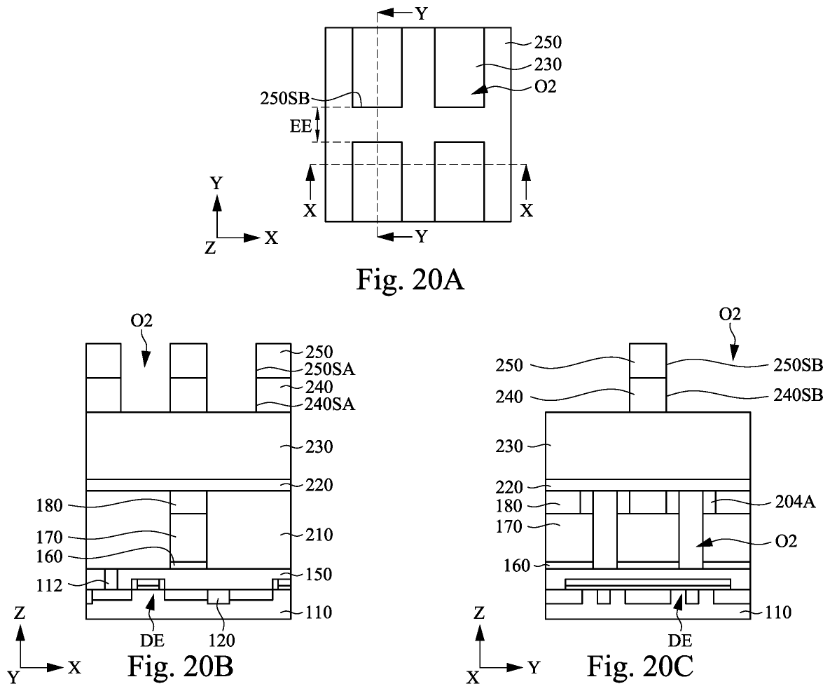

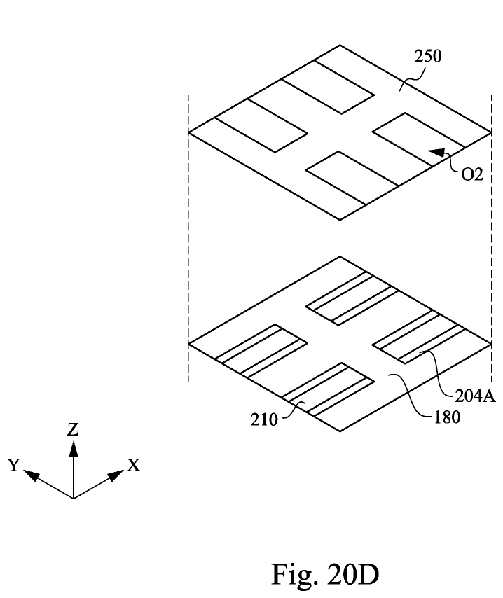

FIGS. 18A-24C illustrate a method for fabricating an integrated circuit device at various intermediate stages of manufacture according to some embodiments of the present disclosure. FIGS. 18A, 19A, 20A, 21A, 22A, 23A, and 24A are top views of the integrated circuit device at the intermediate stages of fabrication process according to some embodiments of the present disclosure. FIGS. 18B, 19B, 20B, 21B, 22B, 23B, and 24B illustrate cross-sectional views taken along a line X-X in FIGS. 18A, 19A, 20A, 21A, 22A, 23A, and 24A, respectively. FIGS. 18C, 19C, 20C, 21C, 22C, 23C, and 24C illustrate cross-sectional views taken along a line Y-Y in FIGS. 18A, 19A, 20A, 21A, 22A, 23A, and 24A, respectively. FIG. 20D is a schematic view of the integrated circuit device showing mappings of a first layer and a second layer over the first layer. It is understood that additional operations may be provided before, during, and after the operations shown by FIGS. 18A-24C, and some of the operations described below can be replaced or eliminated for additional embodiments of the method. The order of the operations/processes may be interchangeable.

Reference is made to FIGS. 18A-18C. After the directional ion beam etch process P1 in FIGS. 5A-5C, skipping the directional ion beam etch process P2 (referring to FIGS. 6A-6C), an etching process is performed to extend the trench openings O1 into the ILD layer 170 as illustrated in FIGS. 7A-7C. The hard mask layer 190 and the via etch stop layer 204A may serve as etch masks during the etching process. The etching process may etch the ILD layer 170 at a faster rate than it etches the etch stop layer 160, and therefore the etch stop layer 160 may serve as an etch stop layer during the first etching process. After etching the trench openings O1 in the ILD layer 170, a liner removal process (also referred to as etching/clean process) may be performed to remove an exposed portion of the etch stop layer 160, thereby extending the trench openings O1 into the etch stop layer 160. Through the etching processes and the liner removal process, top ends of the contact plugs 112 may be exposed by the trench openings O1.

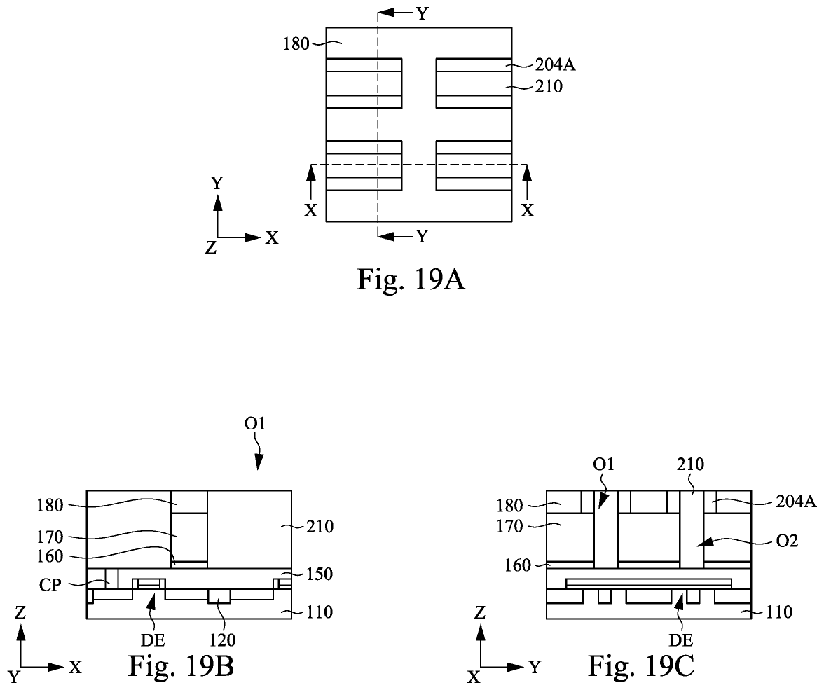

Reference is made to FIGS. 19A-19C. Metal lines 210 are formed in the opening O1 as illustrated in FIGS. 8A-8C. Formation of the metal lines 210 may include filling the trench openings O1 with one or more conductive materials. A CMP process may be performed to remove excess materials of the conductive materials external to the trench openings O1. The CMP process may also remove the hard mask layer 190 from the via etch stop layers 204A and the dielectric layer 180.

Reference is made to FIGS. 20A-20D. An dielectric cap layer 220, an ILD layer 230, a dielectric layer 240, and a hard mask layer 250 are deposited over the dielectric layer 180 as illustrated in FIGS. 9A and 9B. A trench patterning process is then performed to form trench openings O2 extending through the hard mask layer 250 and the dielectric layer 240 in FIGS. 10A-10D.

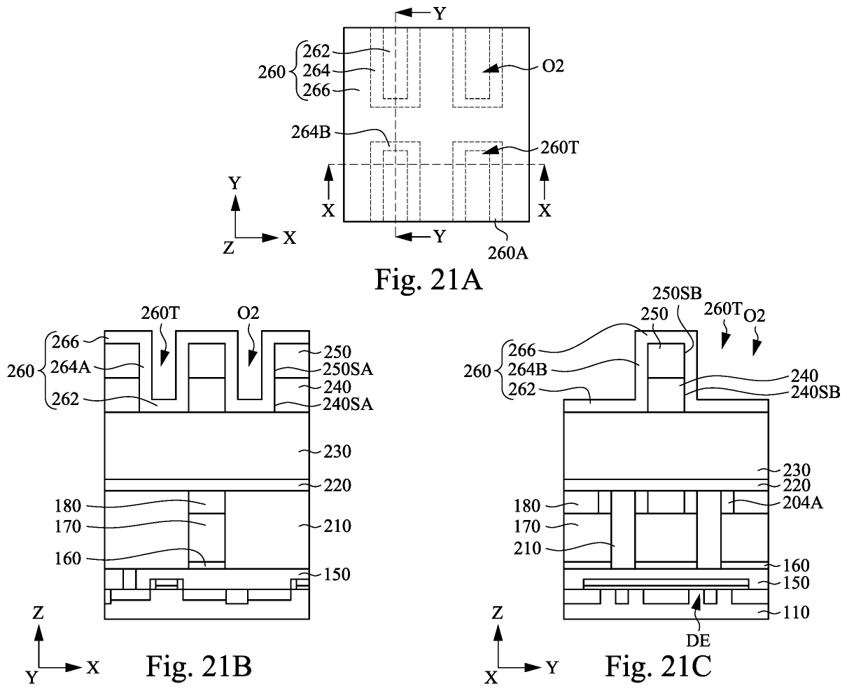

Reference is made to FIGS. 21A-21C. An etch stop layer 260 is conformally deposited over the structure of FIGS. 20A-20D, as illustrated in FIGS. 11A-11C. For example, the etch stop layer 260 may have bottom portions 262 extending along bottoms of the trench openings O2, side portions 264 extending along sidewalls of the trench openings O2, and top portions extending along a top surface of the hard mask layer 250.

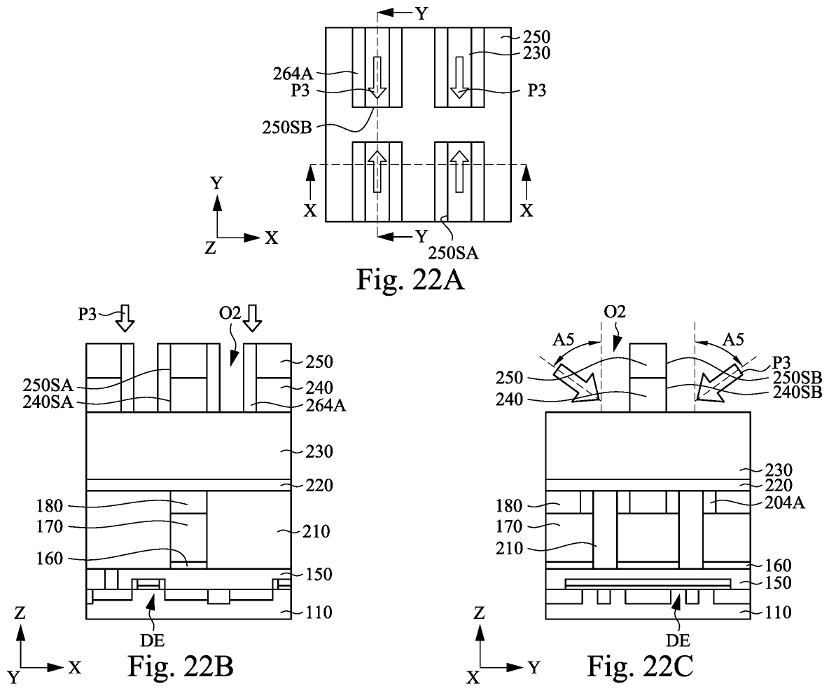

Reference is made to FIGS. 22A-22C. A directional ion beam etch process P3 is performed to remove the side portions 264B of the etch stop layer 260 (referring to FIGS. 21A-21C) from the sidewalls 250SB of the hard mask layer 250 and the sidewalls 240SB of the dielectric layer 240, while the side portions 264A of the etch stop layer 260 remains on sidewalls 250SA of the hard mask layer 250 and the sidewalls 240SA of the dielectric layer 240, as illustrated in FIGS. 12A-12C.

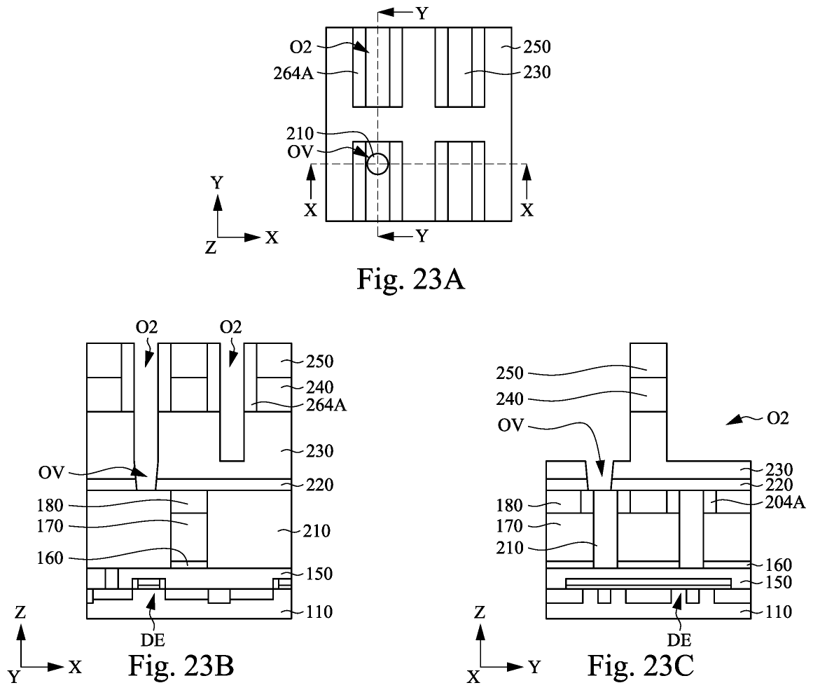

Reference is made to FIGS. 23A-23C. After the directional ion beam etch process P3 in FIGS. 22A-22C, skipping the directional ion beam etch process P4 (referring to FIGS. 13A-13C), a trench and via etching process is performed to extend the trench openings O2 into the ILD layer 230 and etching the via opening OV in the ILD layer 230 as illustrated in FIGS. 14A-14C.

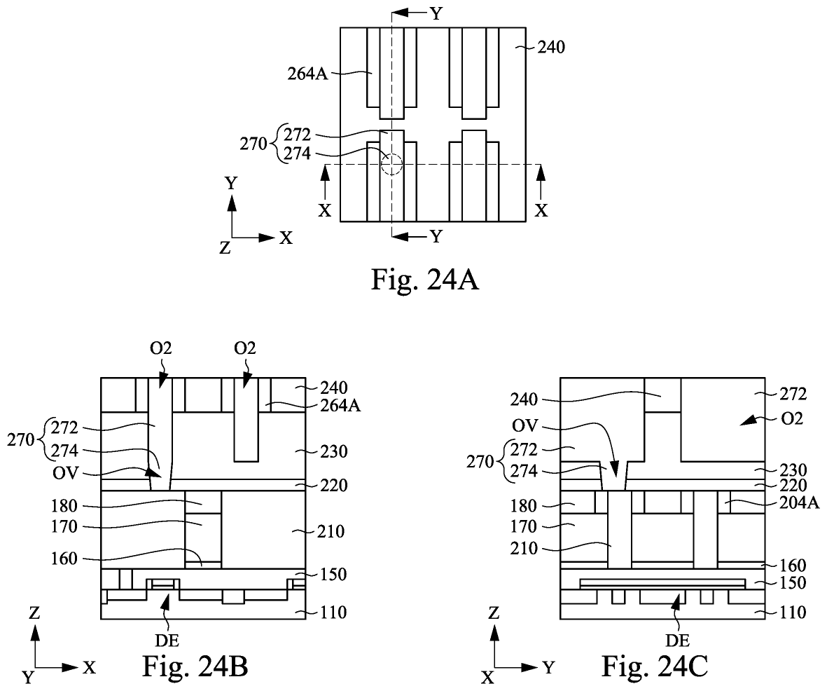

Reference is made to FIGS. 24A-24C. Metal features 270 are formed in the opening O2 and the via opening OV as illustrated in FIGS. 15A-15C. The metal features 270 may include a metal via 272 in the via opening OV and metal lines 274 in the trench openings O2.

In the present embodiments, both the directional ion beam etch process P2 (referring to FIGS. 6A-6C) and the directional ion beam etch process P4 (referring to FIGS. 13A-13C) are skipped. In some alternative embodiments, the directional ion beam etch process P2 (referring to FIGS. 6A-6C) is skipped, and the directional ion beam etch process P4 (referring to FIGS. 13A-13C) is performed. In some alternative embodiments, the directional ion beam etch process P2 (referring to FIGS. 6A-6C) is performed, and the directional ion beam etch process P4 (referring to FIGS. 13A-13C) is skipped. Other details of the present embodiments are similar to those illustrated in FIGS. 1-15C, and therefore not repeated herein.

The directional ion beam etch processes P1-P4 can use ion beam etcher with a suitable etch gases. For example, the etch gases may include CH₄, CH₃F, CH₂F₂, CHF₃, C₄F₈, C₄F₆, CF₄, NF₃, NH₃, H₂, HF, HBr, CO, CO₂, O₂, BCl₃, Cl₂, N₂, He, Ne Kr, Ar, the like, or the combination thereof. The directional ion beam etch processes P1-P4 can be performed with a power in a range from about 100 W to about 3000 W. If the power is greater than about 3000 W, the dielectric layers may be damaged undesirably, and current leakage may occur. If the power is less than about 100 W, the etch stop layer may not be patterned into the via etch stop layer by the directional ion beam etch process. If the directional ion beam etch processes P1-P4 can be performed with a substrate bias in a range from about 0.5 kV to about 20 kV. If the substrate bias is greater than about 20 kV, the dielectric layers may be damaged undesirably, and current leakage may occur. If the substrate bias is less than about 0.5 kV, the etch stop layer may not be patterned into the via etch stop layer by the directional ion beam etch process.

In some embodiments, the one or more etching process in removing dielectric layers, the etch stop layers, the dielectric cap layer, and the hard mask layer can use an etcher (e.g., induced-coupled plasma (ICP), CCP, or remote plasma) or wet clean remove. The etcher may use a suitable etch gases, such as CH₄, CH₃F, CH₂F₂, CHF₃, C₄F₈, CF₆, CF₄, NF₃, NH₃, H₂, HF, HBr, CO, CO₂, O₂, BCl₃, Cl₂, N₂, He, Ne, and Ar, the like, or the combination thereof.

Based on the above discussions, it can be seen that the present disclosure offers advantages to the integrated circuit device. It is understood, however, that other embodiments may offer additional advantages, and not all advantages are necessarily disclosed herein, and that no particular advantage is required for all embodiments. One advantage is that the via etch stop layer is designed adjoining top portions of metal lines. The via etch stop layer may avoid undesired profile of a metal via induced by overlay shift in a next metallization layer, the via overlay window is enlarged, thereby improving electrical performance (e.g., current leakage and voltage breakdown (VBD), time-dependent dielectric breakdown (TDDB), and reliability). Another advantage is that the via etch stop layer has lower capacitance impact in the final structure. Still another advantage is that the end-to-end push process create smaller end-to-end (EE) space between metal lines, thereby increasing interconnect density.

According to some embodiments of the present disclosure, a method for fabricating an integrated circuit device is provided. The method includes depositing a first dielectric layer over a semiconductor substrate; depositing a second dielectric layer over the first dielectric layer; etching a trench opening in the second dielectric layer, wherein the trench opening exposes a first sidewall of the second dielectric layer and a second sidewall of the second dielectric layer, the first sidewall of the second dielectric layer extends substantially along a first direction, and the second sidewall of the second dielectric layer extends substantially along a second direction different from the first direction in a top view; forming a via etch stop layer on the first sidewall of the second dielectric layer, wherein the second sidewall of the second dielectric layer is free from coverage by the via etch stop layer; forming a conductive line in the trench opening; and forming a conductive via over the conductive line.

According to some embodiments of the present disclosure, a method for fabricating an integrated circuit device is provided. The method includes depositing a first dielectric layer over a semiconductor substrate; depositing a second dielectric layer over the first dielectric layer; etching a trench opening in the second dielectric layer, wherein the trench opening extends substantially along a first direction; depositing an etch stop layer into the trench opening; performing a first directional ion beam process to remove a first portion of the etch stop layer, wherein a second portion of the etch stop layer remains in the trench opening, and the first directional ion beam process is tilted with respect to a direction normal to the semiconductor substrate in a cross-sectional view taken along a second direction different from the first direction; forming a conductive line in the trench opening; and forming a conductive via over the conductive line.

According to some embodiments of the present disclosure, an integrated circuit device includes a first conductive line extending substantially along a first direction; a second conductive line above the first conductive line and extending substantially along a second direction different from the first direction; a conductive via connected between the first conductive line and the second conductive line; and a first via etch stop layer adjoining a first sidewall of the first conductive line, wherein a second sidewall of the first conductive line is free of contacting the first via etch stop layer in a first top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an integrated circuit device, comprising:
depositing a first dielectric layer over a semiconductor substrate;
depositing a second dielectric layer over the first dielectric layer;
etching a trench opening in the second dielectric layer, wherein the trench opening exposes a first sidewall of the second dielectric layer and a second sidewall of the second dielectric layer, the first sidewall of the second dielectric layer extends substantially along a first direction, and the second sidewall of the second dielectric layer extends substantially along a second direction different from the first direction in a top view;
forming a via etch stop layer on the first sidewall of the second dielectric layer, wherein the second sidewall of the second dielectric layer is free from coverage by the via etch stop layer;
forming a conductive line in the trench opening; and
forming a conductive via over the conductive line.

2. The method of claim 1, further comprising:
etching the first dielectric layer such that the trench opening further extends into the first dielectric layer after forming the via etch stop layer.

3. The method of claim 1, wherein the conductive via is in contact with the via etch stop layer.

4. The method of claim 1, further comprising:
depositing a third dielectric layer over the second dielectric layer; and
etching a via opening in the third dielectric layer to expose the via etch stop layer and the conductive line, and forming the conductive via is performed such that the conductive via is in the via opening.

5. The method of claim 1, wherein forming the via etch stop layer comprises:
depositing an etch stop layer over the second dielectric layer, wherein the etch stop layer has a first portion on a first sidewall of the second dielectric layer and a second portion on a second sidewall of the second dielectric layer; and
removing the second portion of the etch stop layer from the second sidewall of the second dielectric layer, while the first portion of the etch stop layer remains on the first sidewall of the second dielectric layer and serves as the via etch stop layer.

6. The method of claim 5, wherein removing the second portion of the etch stop layer from the second sidewall of the second dielectric layer comprises:
performing a directional ion beam process, wherein a direction of the directional ion beam process is tilted with respect to a direction normal to the semiconductor substrate in a cross-sectional view taken along the second direction.

7. The method of claim 5, wherein removing the second portion of the etch stop layer from the second sidewall of the second dielectric layer comprises:
performing a directional ion beam process, wherein a direction of the directional ion beam process is tilted at a first angle with respect to a direction normal to the semiconductor substrate in a cross-sectional view taken along the first direction, the direction of the directional ion beam process is tilted at a second angle with respect to the direction normal to the semiconductor substrate in a cross-sectional view taken along the second direction, and the second angle is greater than the first angle.

8. The method of claim 1, further comprising:
pushing the second sidewall of the second dielectric layer away from a center of the trench opening prior to etching the first dielectric layer.

9. The method of claim 8, wherein pushing the second sidewall of the second dielectric layer away from the center of the trench opening comprises:
performing a directional ion beam process, wherein a direction of the directional ion beam process is tilted with respect to a direction normal to the semiconductor substrate in a cross-sectional view taken along the second direction.

10. The method of claim 8, wherein pushing the second sidewall of the second dielectric layer away from the center of the trench opening comprises:
performing a directional ion beam process, wherein a direction of the directional ion beam process is tilted at a first angle with respect to a direction normal to the semiconductor substrate in a cross-sectional view taken along the first direction, the direction of the directional ion beam process is tilted at a second angle with respect to the direction normal to the semiconductor substrate in a cross-sectional view taken along the second direction, and the second angle is greater than the first angle.

11. A method for fabricating an integrated circuit device, comprising:
depositing a first dielectric layer over a semiconductor substrate;
depositing a second dielectric layer over the first dielectric layer;
depositing a hard mask layer over the second dielectric layer;
etching a trench opening in the hard mask layer and second dielectric layer, wherein the trench opening extends substantially along a first direction, and the trench opening exposes a portion of the first dielectric layer;
depositing an etch stop layer into the trench opening;
performing a first directional ion beam process, wherein the first directional ion beam process is tilted with respect to a direction normal to the semiconductor substrate in a cross-sectional view taken along a second direction different from the first direction, wherein a sidewall of the hard mask layer and a sidewall of the second dielectric layer are exposed by the etch stop layer after the first directional ion beam process;
forming a first conductive line in the trench opening; and
forming a conductive feature comprising a conductive via over the first conductive line.

12. The method of claim 11, wherein the second dielectric layer comprises a material different from the first dielectric layer.

13. The method of claim 11, wherein forming the conductive feature is performed such that the conductive feature comprises a second conductive line over the conductive via, wherein the first conductive line extends substantially along the first direction, and the second conductive line extends substantially along the second direction.

14. The method of claim 11, further comprising:
etching away the portion of the first dielectric layer exposed by the trench opening after the first directional ion beam process and prior to forming the first conductive line.

15. The method of claim 11, further comprising:
removing the hard mask layer from the second dielectric layer after etching away the portion of the first dielectric layer and prior to forming the first conductive line.

16. The method of claim 11, wherein depositing the etch stop layer into the trench opening is performed such that the etch stop layer has a bottom portion in contact with the portion of the first dielectric layer exposed by the trench opening, and the first directional ion beam process is performed to remove the bottom portion of the etch stop layer.

17. An integrated circuit device, comprises:
a first conductive line extending substantially along a first direction;
a second conductive line above the first conductive line and extending substantially along a second direction different from the first direction;
a conductive via connected between the first conductive line and the second conductive line; and
a first via etch stop layer adjoining a first sidewall of the first conductive line, wherein a second sidewall of the first conductive line is free of contacting the first via etch stop layer in a first top view.

18. The integrated circuit device of claim 17, wherein the conductive via is in contact with a top end of the first via etch stop layer.

19. The integrated circuit device of claim 17, wherein a bottom end of the first via etch stop layer is higher than a bottom surface of the first conductive line.

20. The integrated circuit device of claim 17, further comprising:
a second via etch stop layer adjoining a third sidewall of the second conductive line, wherein a fourth sidewall of the second conductive line is free of contacting the second via etch stop layer in a second top view.
